(19) United States
(12) Patent Application Publication
(10) Pub. No.: US 2025/0202524 A1
(43) Pub. Date: Jun. 19, 2025

(54) RF SPDT SWITCH SYSTEM FOR DIFFERENTIAL SIGNAL CONVERSION

(71) Applicant: ELECTRONICS AND TELECOMMUNICATIONS RESEARCH INSTITUTE, Daejeon (KR)

(72) Inventors: Sun Woo KONG, Daejeon (KR); Bong Hyuk PARK, Daejeon (KR); Seung Hun WANG, Daejeon (KR); Hui Dong LEE, Daejeon (KR); Seung Hyun JANG, Daejeon (KR); Jung Hwan HWANG, Daejeon (KR)

(21) Appl. No.: 18/977,583

(22) Filed: Dec. 11, 2024

(30) Foreign Application Priority Data
Dec. 14, 2023 (KR) 10-2023-0182396

(51) Int. Cl. H04B 1/44; H03K 17/00

(52) U.S. Cl. CPC H04B 1/44; H03K 17/007

(57) ABSTRACT

A radio frequency (RF) SPDT (single pole double throw) switch device for differential signal conversion is disclosed. According to one embodiment of the present disclosure, an RF SPDT switch device for differential signal conversion may include a central metal line; a first metal line and a second metal line connected to a first direction side of the central metal line; and a third metal line and a fourth metal line connected to a second direction side of the central metal line.

### CROSS-REFERENCE TO RELATED APPLICATION

This application claims the benefit of earlier filing date and right of priority to Korean Patent Application No. 10-2023-0182396, filed on Dec. 14, 2023, the contents of which are all hereby incorporated by reference herein in their entirety.

### TECHNICAL FIELD

The present disclosure relates to a radio frequency switch, and more particularly, to an RF single-pole double-throw (SPDT) switch system for differential signal conversion.

### BACKGROUND

The RF SPDT switch is one of the RF switches used in a wireless communication system. As shown in FIG. 1, the RF SPDT switch (10) can perform the role of selecting one of two input ports and connecting it to an output port.

Meanwhile, in the case of time division duplex (TDD), receiving and transmitting operations can be performed alternately over time.

Here, a block that connects and controls the transmitting and receiving blocks of the antenna may be required. The block can determine the operation and timing of operation to be received on the TDD system, and manage the connection between the antenna and other devices.

### SUMMARY

The technical problem of the present disclosure is to provide an RF SPDT switch system for differential signal conversion.

The technical problem of the present disclosure is to provide an RF SPDT switch system that reduces performance degradation due to parasitic components at high frequencies and is suitable for a multi-channel chip structure.

The technical problems to be achieved in the present disclosure are not limited to the technical tasks mentioned above, and other technical problems not mentioned will be clearly understood by those skilled in the art from the description below.

According to one embodiment of the present disclosure, a radio frequency (RF) single pole double throw (SPDT) switch device for differential signal conversion may include a central metal line; a first metal line and a second metal line connected to a first direction side of the central metal line; and a third metal line and a fourth metal line connected to a second direction side of the central metal line, and an antenna port may be connected to one end of the central metal line and the other end may be open, and a first differential port may be connected to one end in a direction in which the first metal line and the second metal line face each other, and a second differential port may be connected to one end in a direction in which the third metal line and the fourth metal line face each other.

In addition, a length of the central metal line may be half of a wavelength (Δ) of a signal input as the antenna signal, and a length of each of the first metal line, the second metal line, the third metal line, and the fourth metal line may be Δ/4.

In addition, the first differential port may be one of a transmission (Tx) port or a reception (Rx) port, and the second differential port may be the other of the transmission port or the reception port.

In addition, a first transistor may be connected to one end of the first metal line and the second metal line facing each other, and a second transistor connected to ground (GND) may be connected to the other end of each of the first metal line and the second metal line.

In addition, a third transistor may be connected to one end of the third metal line and the fourth metal line facing each other, and a fourth transistor connected to GND may be connected to the other end of each of the third metal line and the fourth metal line.

In addition, based on a high signal being input to a gate of each of the second transistor or the fourth transistor, each of the second transistor or the fourth transistor may be controlled to be connected to the GND, and based on a low signal being input to the gate of each of the second transistor or the fourth transistor, each of the second transistor or the fourth transistor may be controlled to be opened.

In addition, based on a high signal being input to a gate of each of the first transistor or the third transistor, a plurality of metal lines connected to each of the first transistor or the third transistor may be controlled to be connected, and based on a low signal being input to the gate of each of the first transistor and the third transistor, the first transistor and the third transistor may be controlled to be opened.

In addition, based on the first differential port being a transmitting port, the second differential port being a receiving port, and a single-ended reception signal being input from the antenna port: the first transistor may be closed, the second transistor may be opened, the third transistor may be opened, and the fourth transistor may be short-circuited

In addition, the single-ended reception signal may be converted into a differential signal and received at the reception port.

In addition, based on the first differential port being a transmitting port, the second differential port being a receiving port, and a single-ended transmission signal being input from the antenna port: the first transistor may be opened, the second transistor may be short-circuited, the third transistor may be short-circuited, and the fourth transistor may be opened.

In addition, the single-ended reception signal may be converted into a differential signal and transmitted at the transmission port.

According to one embodiment of the present disclosure, a Multi-channel chip may include a transmission circuit; a reception circuit; and a radio frequency (RF) single pole double throw (SPDT) switch device for differential signal conversion arranged between the transmission circuit and the reception circuit, and the RF SPDT switch device connected to the transmission circuit and the reception circuit may include: a central metal line; a first metal line and a second metal line connected to a first direction side of the central metal line; and a third metal line and a fourth metal line connected to a second direction side of the central metal line, and an antenna port may be connected to one end of the central metal line and the other end is open, and a first differential port may be connected to one end in a direction in which the first metal line and the second metal line face each other, and a second differential port may be connected to one end in a direction in which the third metal line and the fourth metal line face each other.

According to one embodiment of the present disclosure, a method of controlling a radio frequency (RF) SPDT ((single pole double throw) switch device including an antenna port may include receiving a single-ended signal through the antenna port; and converting the single-ended signal into a differential-ended signal and transmitting it to a transmission port or a reception port, and A radio frequency (RF) single pole double throw (SPDT) switch device for differential signal conversion, the RF SPDT switch device may include a central metal line; a first metal line and a second metal line connected to a first direction side of the central metal line; and a third metal line and a fourth metal line connected to a second direction side of the central metal line, and an antenna port may be connected to one end of the central metal line and the other end is open, and a first differential port may be connected to one end in a direction in which the first metal line and the second metal line face each other, and a second differential port may be connected to one end in a direction in which the third metal line and the fourth metal line face each other.

The features briefly summarized above with respect to the disclosure are merely exemplary aspects of the detailed description of the disclosure that follows, and do not limit the scope of the disclosure.

According to embodiments of the present disclosure, an RF SPDT switch system for differential signal conversion can be provided.

According to embodiments of the present disclosure, an RF SPDT switch system that reduces performance degradation due to parasitic components at high frequencies and is suitable for a multi-channel chip structure can be provided.

The effects obtainable in the present disclosure are not limited to the effects mentioned above, and other effects not mentioned will be clearly understood by those skilled in the art from the description below.

### BRIEF DESCRIPTION OF THE DRAWINGS

FIG. 1 is a diagram schematically illustrating the location and structure of an RF SPDT switch.

FIG. 2 is a diagram for describing a SPST switch connection structure and a structure using a Δ/4 line.

FIG. 3 is a diagram for describing a differential RF SPDT switch block diagram according to an embodiment of the present disclosure.

FIG. 4 is a diagram for describing a structure of a differential RF SPDT switch device according to an embodiment of the present disclosure.

FIG. 5A is a diagram for describing a process of performing a receiving operation through a differential RF SPDT switch according to an embodiment of the present disclosure.

FIG. 5B is a diagram for describing a process of performing a transmitting operation through a differential RF SPDT switch according to an embodiment of the present disclosure.

FIG. 6 shows an example of a chip on which a differential RF SPDT device is arranged according to an embodiment of the present disclosure.

FIG. 7 illustrates a simulation experiment result reflecting EM results according to one embodiment of the present disclosure.

FIG. 8 illustrates a configuration of a device including a multi-channel chip according to one embodiment of the present disclosure.

### DETAILED DESCRIPTION

Since the present disclosure can make various changes and have various embodiments, specific embodiments are illustrated in the drawings and described in detail in the detailed description. However, this is not intended to limit the present disclosure to specific embodiments, and should be understood to include all modifications, equivalents, and substitutes included in the idea and scope of the present disclosure. Similar reference numbers in the drawings indicate the same or similar function throughout the various aspects.

The shapes and sizes of elements in the drawings may be exaggerated for clarity. Detailed description of exemplary embodiments to be described later refers to the accompanying drawings, which illustrate specific embodiments by way of example. These embodiments are described in sufficient detail to enable those skilled in the art to practice the embodiments. It should be understood that the various embodiments are different, but need not be mutually exclusive. For example, specific shapes, structures, and characteristics described herein may be implemented in another embodiment without departing from the idea and scope of the present disclosure in connection with one embodiment. Additionally, it should be understood that the location or arrangement of individual components within each disclosed embodiment may be changed without departing from the spirit and scope of the embodiment. Accordingly, the detailed description set forth below is not to be taken in a limiting sense, and the scope of the exemplary embodiments, if properly described, is limited only by the appended claims, along with all equivalents as claimed by those claims.

In this disclosure, terms such as first and second may be used to describe various components, but the components should not be limited by the terms. These terms are only used for the purpose of distinguishing one component from another. For example, a first element may be termed a second element, and similarly, a second element may be termed a first element, without departing from the scope of the present disclosure. The term and/or includes a combination of a plurality of related recited items or any one of a plurality of related recited items.

When an element of the present disclosure is referred to as being “connected” or “connected” to another element, it may be directly connected or connected to the other element, but it should be understood that other components may exist in the middle. On the other hand, when an element is referred to as “directly connected” or “directly connected” to another element, it should be understood that no other element exists in the middle.

Components appearing in the embodiments of the present disclosure are shown independently to represent different characteristic functions, and do not mean that each component is composed of separate hardware or a single software component. That is, each component is listed and included as each component for convenience of description, and at least two components of each component are combined to form one component, or one component can be divided into a plurality of components to perform functions. An integrated embodiment and a separate embodiment of each of these components are also included in the scope of the present disclosure unless departing from the essence of the present disclosure.

Terms used in the present disclosure are only used to describe specific embodiments, and are not intended to limit the present disclosure. Singular expressions include plural expressions unless the context clearly dictates otherwise. In the present disclosure, terms such as “comprise” or “have” are intended to designate that there are features, numbers, steps, operations, components, parts, or combinations thereof described in the specification, and it should be understood that this does not preclude the possibility of the presence or addition of one or more other features, numbers, steps, operations, components, parts, or combinations thereof. That is, the description of “including” a specific configuration in the present disclosure does not exclude configurations other than the corresponding configuration, and means that additional configurations may be included in the practice of the present disclosure or the scope of the technical spirit of the present disclosure.

Some of the components of the present disclosure may be optional components for improving performance rather than essential components that perform essential functions in the present disclosure. The present disclosure may be implemented including only components essential to implement the essence of the present disclosure, excluding components used for performance improvement, and a structure including only essential components excluding optional components used only for performance improvement is also included in the scope of the present disclosure.

Hereinafter, embodiments of the present disclosure will be described in detail with reference to the drawings. In describing the embodiments of this specification, if it is determined that a detailed description of a related known configuration or function may obscure the gist of the present specification, the detailed description will be omitted. The same reference numerals are used for the same components in the drawings, and redundant descriptions of the same components are omitted.

The system and/or method/device (hereinafter simply referred to as the ‘system’) proposed in the present disclosure relates to a technology related to an RF SPDT switch structure for differential signal conversion.

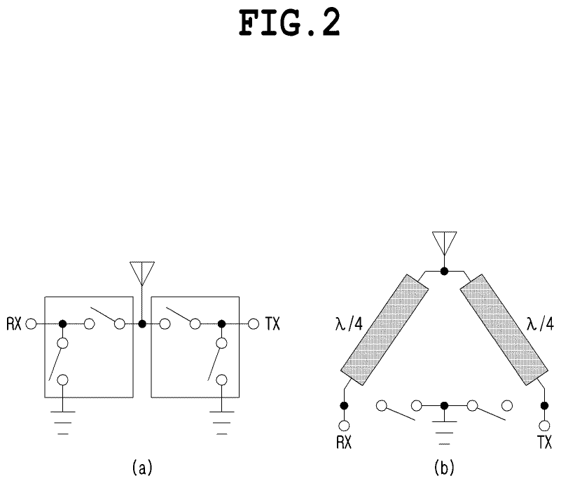

Previously, the SPST switch connection structure shown in (a) of FIG. 2 and the structure using the Δ/4 line shown in (b) of FIG. 2 were developed and utilized.

As shown in (a) of FIG. 2, the SPST switch connection structure represents a connection method of a single-polarity transmission switch. The SPST switch connection structure may have different operation modes for each of a transmission operation and a reception operation.

At the transmitting end, the series transistor may be operated with the short transistor closed and the short transistor open, and at the receiving end, the opposite may be operated.

However, in the case of the SPST switch connection structure, there is a disadvantage that a lot of loss may occur due to the parasitic components of the transistor at high frequencies and the isolation is low.

That is, energy may be lost while a signal is transmitted within a circuit based on an SPST switch connection structure, and the operation performance of a communication system may be degraded due to insufficient isolation between transmission and reception.

As shown in (b) of FIG. 2, the Δ/4 line used for frequency operation means a radio transmission line having a length corresponding to ¼ of the wavelength of the radio wave.

When performing a transmission operation, the short transistor of the transmitting end is kept open, and the receiving end may be operated in the opposite manner.

Due to this, the receiving port may appear to have an infinitely increasing resistance (i.e., high impedance or High-Z) by the Δ/4 line. This may be used as one of the methods for effectively transmitting and receiving radio signals.

However, in addition to this switching operation, the function of converting a single signal into a differential signal is missing, and a structure using a Δ/4 line may require an additional block such as a balun.

In order to secure frequency bandwidth, the frequency may increase to millimeter waves or/and terahertz waves, and accordingly, the insertion loss of the RF switch may increase and the isolation may decrease. The increase in the insertion loss and the decrease in the isolation of the RF switch may be caused by the influence of parasitic components.

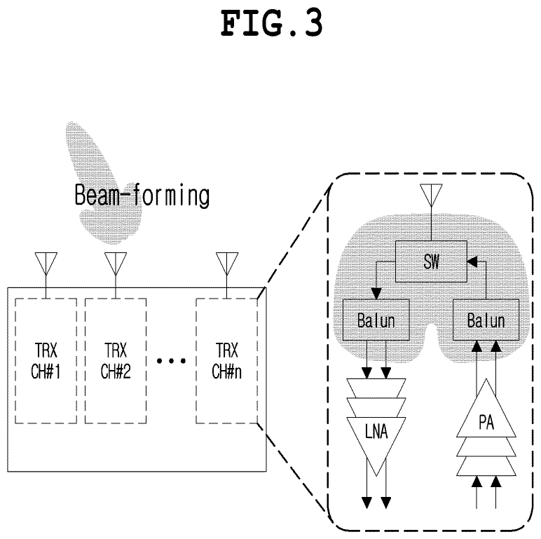

In order to improve transmission and reception performance at high frequencies, beamforming technology may be applied as shown in FIG. 3, and for this purpose, a multi-channel chip structure is essential. In a multi-channel chip structure, a differential structure must be applied to the transmission and reception terminals in order to obtain equal performance in each channel.

Also, since the optimal antenna spacing for beamforming is Δ/2, which is half the wavelength, the spacing between Tx and Rx must also be narrowed to satisfy this.

Hereinafter, a structure of an RF SPDT switch suitable for a multi-channel chip structure while reducing performance degradation due to parasitic components at high frequencies such as millimeter waves or terahertz waves according to one embodiment of the present disclosure will be described.

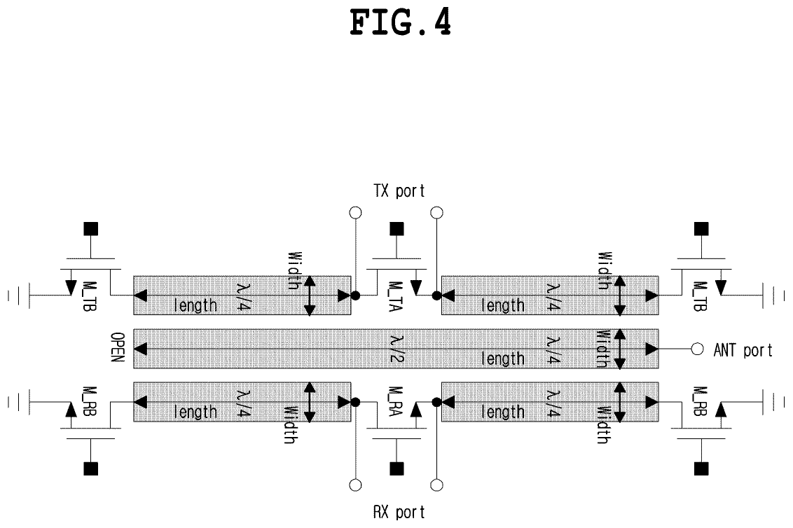

FIG. 4 is a drawing for describing the structure of a differential RF SPDT switch device according to one embodiment of the present disclosure.

The differential RF SPDT switch illustrated in FIG. 4 may operate at high frequencies such as millimeter waves or/and terahertz waves.

Differential RF SPDT switch devices may control the transmission of signals within a device and/or circuit. As described above, SPDT switch devices are a general term for switches that can convert one input signal to two different outputs.

The differential RF SPDT switch device may convert a single-ended signal into a differential signal (i.e., a pair-ended signal). The differential signal may provide strong immunity to noise and reduce performance deviation for each channel in a multi-channel chip.

Differential RF SPDT switch devices may have immunity to RF ESD (electro-static discharge). That is, differential RF SPDT switch devices may have immunity to ESD while operating normally under RF.

Additionally, the arrangement of the transmitter circuit and the receiver circuit may be facilitated by considering the area within the differential RF SPDT switch device. Specifically, when designing the differential RF SPDT switch device, the transmitter circuit and the receiver circuit can be easily arranged by considering space efficiency. This can reduce the complexity of the design and increase the cost efficiency.

### Configuration of Differential RF SPDT Switch Device

As illustrated in FIG. 4, the differential RF SPDT switch may be composed of five metal lines having a characteristic impedance of Z0. That is, by applying the width value of the metal line having a characteristic impedance of Z0, the differential RF SPDT switch may be composed of five metal lines.

The length of the central metal line among the five metal lines may be Δ/2, but is not limited thereto.

Two metal lines may be configured in the form of a Marchand balun in each of the first direction (e.g., rightward direction) and the second direction (e.g., leftward direction) planes based on the central metal line, and the centers of the two metal lines may be open.

For example, the metal lines connected to the first direction side of the central metal line may be the first metal line and the second metal line, and the metal lines connected to the second direction side of the central metal line may be the third metal line and the fourth metal line.

The length of each of the two metal lines located on both sides based on the central metal line may be Δ/4, but is not limited thereto.

One side of the central metal line may be configured as an input/output port (ANT port) to which an antenna is connected, and the other side may be open.

A differential port may be connected to the two metal lines with a length of Δ/4 located on both sides of the central metal line facing each other.

For example, a first differential port may be connected to one end in which the first metal line and the second metal line face each other, and a second differential port may be connected to one end in which the third metal line and the fourth metal line face each other.

As an example of the present disclosure, as illustrated in FIG. 4, the left-side differential port may be configured as a Tx port and the right-side differential port may be configured as an Rx port, but is not limited thereto. The right-side port may be configured as a Tx port and the left-side port may be configured as an Rx port.

A transistor (e.g., MR_B, MT_B) connected to ground may be connected to the other end (i.e., the end in the direction not facing each other) of two metal lines each having a length of Δ/4 located on the left and right sides with respect to the central metal line.

And, two metal lines with a length of Δ/4 located on the right and left sides with respect to the central metal line may have one end facing each other, and a transistor (e.g., MR_A, MT_A) that can connect the metal lines to each other may be connected.

As an example of the present disclosure, MR_B and MT_B may be connected to GND when a high signal is input to the gate, and may be opened when a low signal is input to the gate.

Additionally, MR_A and MT_A may connect two Δ/4 metal lines when a high signal is input to the gate, and may be opened when a low signal is input to the gate.

### Operation of Differential RF SPDT Switch Device

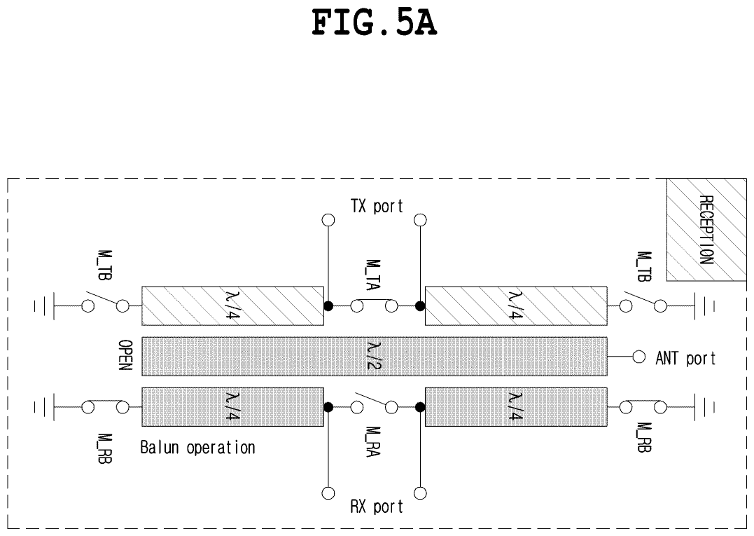

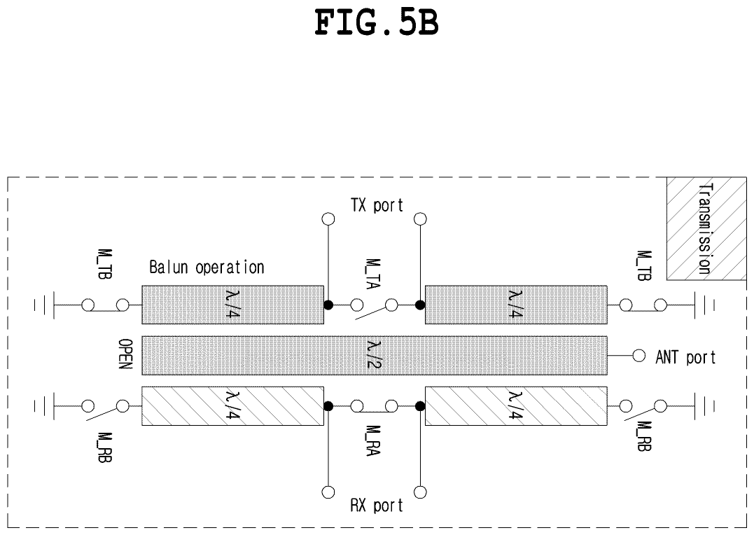

As one embodiment of the present disclosure, FIG. 5A is a diagram for describing a process of performing a receiving operation through a differential RF SPDT switch.

Specifically, when M_RB and M_TA are closed and M_RA and M_TB are opened, the receiving operation of the differential RF SPDT switch device may be performed.

When the two metal lines connected to the Rx port by M_RB are connected to GND, the two metal lines connected to the center metal and the Rx port may operate like a Marchand balun (i.e., the signal input through the ANT port is transmitted as a differential signal toward the Rx port).

Here, the ends of the two metal lines connected to the Tx port may appear as High Z by the open M_TB, and the Marchand balun may lose its operability.

In addition, the isolation may be increased by connecting each of the two metal lines connected to the Tx port by M_TA.

As another example of the present disclosure, FIG. 5B is a diagram for explaining a process of performing a transmission operation through a differential RF SPDT switch.

Specifically, when M_RA and M_TB are closed and M_TA and M_RB are opened, a transmission operation of the differential RF SPDT switch device may be performed.

When the two metal lines connected to the Rx port by M_TB are connected to GND, the two metal lines connected to the center metal and the Tx port may operate like a Marchand balun (i.e., transfer the differential signal on the Tx port side to a single-ended signal on the ANT port side).

Here, the ends of the two metal lines connected to the Rx port may appear as High Z by the open M_RB, and the Marchand balun may lose its operability.

In addition, the isolation may be increased by connecting each of the two metal lines connected to the Rx port by M_RA.

As described above, when the SPST switch device illustrated in FIG. 2 is used, the loss may be large and the isolation may be low due to the parasitic components of the transistor. That is, when a transistor is used, there is a problem that the signal loss is large and the signals are not isolated from each other, making it difficult to obtain the desired performance.

Additionally, if the SPST switch device illustrated in FIG. 2 is utilized, an additional balun (e.g., a balun that operates as a transformer) may be required and additional RF ESD may be required.

As additional baluns are applied, insertion loss increases, circuit area increases, and bandwidth may be limited. Additional circuitry and devices are required for RF ESD protection, which may be a design and cost disadvantage.

When a Δ/4 line-based switch device as shown in FIG. 3 is used, high isolation performance can be obtained only when two Δ/4 lines do not have coupling with each other. There is a problem that layout for high isolation performance is required, and this may increase the area occupied by the circuit.

Additionally, when the Δ/4 line-based switch device illustrated in FIG. 3 is used, additional baluns and RF ESD may be additionally required, as in the SPST switch device.

In one embodiment of the present disclosure, the differential RF SPDT device illustrated in FIG. 4 may convert a single-ended signal into an analog signal. That is, a single-ended signal may be converted into a differential signal by the differential RF SPDT device, and is suitable for a multi-channel configuration.

Since no series transistor is included on the differential RF SPDT device and no additional balun is required, loss due to parasitic components can be reduced, and low insertion loss and wide bandwidth can be secured according to the characteristics of the Marchand balun.

Additionally, the layout arrangement of the transmit/receive switches of the differential RF SPDT devices may not require a large width. And, the differential RF SPDT devices can operate like RF ESDs operating at high frequencies.

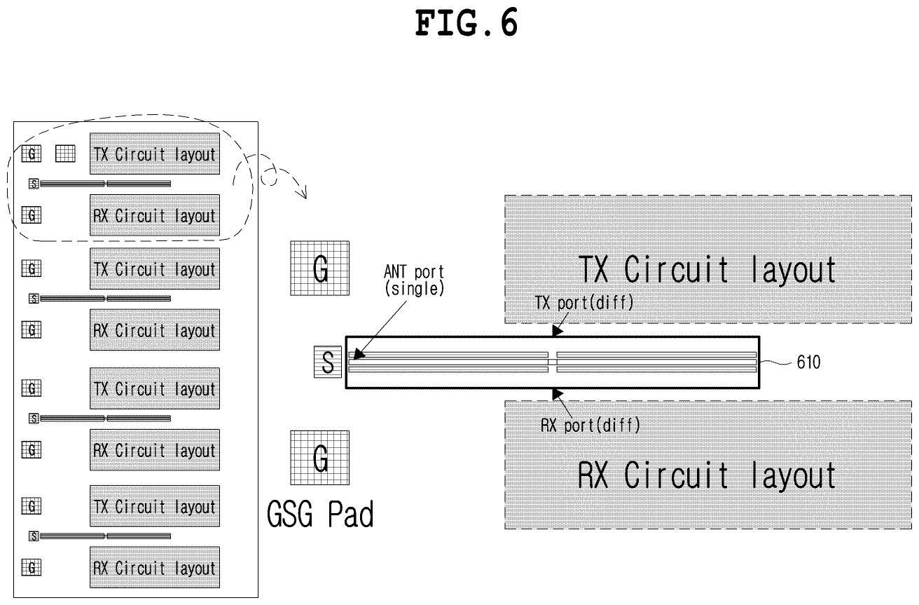

FIG. 6 illustrates an example of a chip having a differential RF SPDT device disposed thereon, according to one embodiment of the present disclosure.

That is, FIG. 6 illustrates a structure for arranging the differential RF SPDT device of the present disclosure when manufacturing an actual chip.

When arranged as a 4-channel transceiver chip, the Tx circuit and the Rx circuit can be arranged in parallel, and the differential RF SPDT device of the present disclosure can be arranged between the Tx circuit and the Rx circuit.

Therefore, when configuring a chip with a GSG (ground-signal-ground) pad height size, it can be of great help in configuring a multi-channel chip that must maintain an antenna spacing of Δ/2.

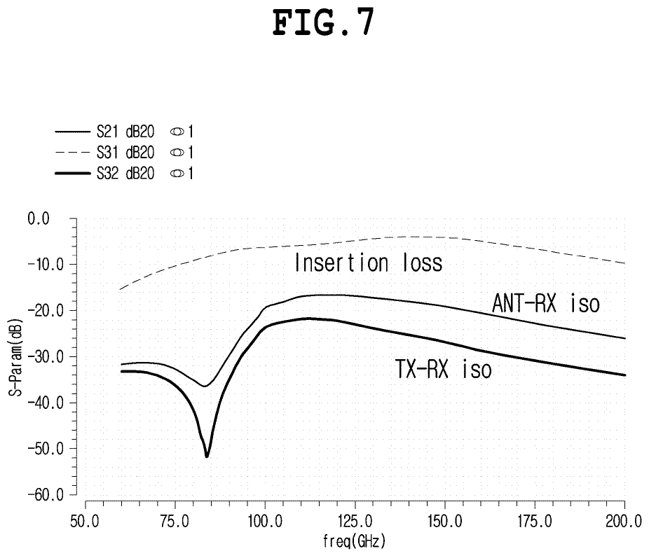

FIG. 7 illustrates the results of a simulation experiment reflecting EM results according to one embodiment of the present disclosure.

That is, FIG. 7 illustrates the experimental results of insertion loss, Tx-Rx isolation, Ant-Rx isolation, and bandwidth when the Tx port operates at 140 GHz and the Rx port does not operate (i.e., when performing the transmission operation illustrated in FIG. 5B). The experimental results are as shown in Table 1.

TABLE 1

| | |
|---|---|
| Insertion loss | 3.98 dB |
| TX-RX Isolation | 25.2 dB |
| Antenna-RX isolation | 18.1 dB |
| BW | 91 GHz to 180 GHz |

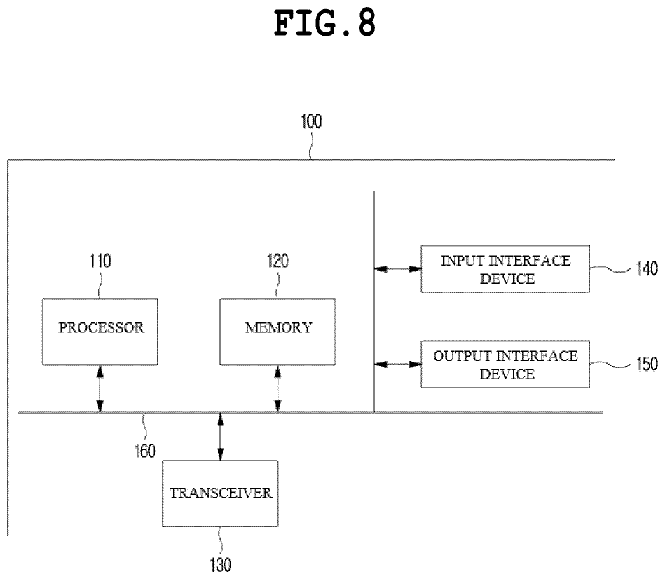

FIG. 8 illustrates a configuration of a device including a multi-channel chip according to one embodiment of the present disclosure.

Specifically, the device (100) in FIG. 8 may collectively refer to various types of devices including a multi-channel chip composed of a plurality of transmitting circuits, receiving circuits, and RF SPDT devices.

The device (100) may include at least one of a processor (110), a memory (120), a transceiver (130), an input interface device (140), and an output interface device (150). Each of the components may be connected to each other by a common bus (160). In addition, each of the components may be connected to each other through an individual interface or individual bus centered on the processor (110), rather than the common bus (160).

The processor (110) may be implemented in various types such as an AP (Application Processor), a CPU (Central Processing Unit), a GPU (Graphic Processing Unit), etc., and may be any semiconductor device that executes a command stored in the memory (120). The processor (110) may execute a program command stored in the memory (120).

A multi-channel chip may be included on any semiconductor device included in the processor (110) and/or the transceiver (130). The processor (110) may process a single-ended signal received from an antenna port by controlling the multi-channel chip.

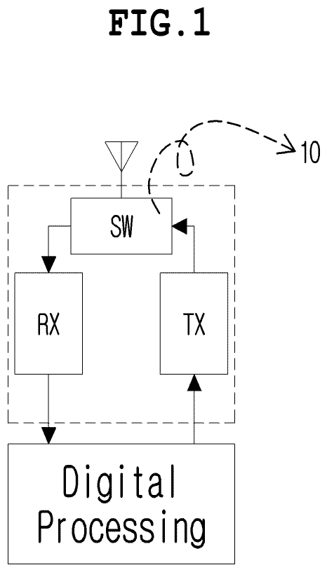

And/or, the processor (110) may store program instructions for implementing at least one function for one or more modules in the memory (120) to control the operations described based on FIGS. 1 to 7 to be performed. That is, each operation and/or function according to FIGS. 1 to 7 may be executed by one or more processors (110).

The memory (120) may include various forms of volatile or non-volatile storage media. For example, the memory (120) may include a read-only memory (ROM) and a random access memory (RAM). In an embodiment of the present disclosure, the memory (120) may be located inside or outside the processor (110), and the memory (120) may be connected to the processor (110) through various means already known.

The transceiver (130) may perform a function of transmitting and receiving data processed/to be processed by the processor (110) with an external device and/or an external system.

For example, the transceiver (130) may be utilized for data exchange with other terminal devices, etc.

The input interface device (140) may be configured to provide data to the processor (110).

The output interface device (150) may be configured to output data from the processor (110).

Components described in the exemplary embodiments of the present disclosure may be implemented by hardware elements. For example, The hardware element may include at least one of a digital signal processor (DSP), a processor, a controller, an application specific integrated circuit (ASIC), a programmable logic element such as an FPGA, a GPU, other electronic devices, or a combination thereof. At least some of the functions or processes described in the exemplary embodiments of the present disclosure may be implemented as software, and the software may be recorded on a recording medium. Components, functions, and processes described in the exemplary embodiments may be implemented as a combination of hardware and software.

The method according to an embodiment of the present disclosure may be implemented as a program that can be executed by a computer, and the computer program may be recorded in various recording media such as magnetic storage media, optical reading media, and digital storage media.

Various techniques described in this disclosure may be implemented as digital electronic circuits or computer hardware, firmware, software, or combinations thereof. The above techniques may be implemented as a computer program product, that is, a computer program or computer program tangibly embodied in an information medium (e.g., machine-readable storage devices (e.g., computer-readable media) or data processing devices), a computer program implemented as a signal processed by a data processing device or propagated to operate a data processing device (e.g., a programmable processor, computer or multiple computers).

Computer program(s) may be written in any form of programming language, including compiled or interpreted languages. It may be distributed in any form, including stand-alone programs or modules, components, subroutines, or other units suitable for use in a computing environment. A computer program may be executed by a single computer or by a plurality of computers distributed at one or several sites and interconnected by a communication network.

Examples of information medium suitable for embodying computer program instructions and data may include semiconductor memory devices (e.g., magnetic media such as hard disks, floppy disks, and magnetic tapes), optical media such as compact disk read-only memory (CD-ROM), digital video disks (DVD), etc., magneto-optical media such as floptical disks, and ROM (Read Only Memory), RAM (Random Access Memory), flash memory, EPROM (Erasable Programmable ROM), EEPROM (Electrically Erasable Programmable ROM) and other known computer readable media. The processor and memory may be complemented or integrated by special purpose logic circuitry.

A processor may execute an operating system (OS) and one or more software applications running on the OS. The processor device may also access, store, manipulate, process and generate data in response to software execution. For simplicity, the processor device is described in the singular number, but those skilled in the art may understand that the processor device may include a plurality of processing elements and/or various types of processing elements. For example, a processor device may include a plurality of processors or a processor and a controller. Also, different processing structures may be configured, such as parallel processors. In addition, a computer-readable medium means any medium that can be accessed by a computer, and may include both a computer storage medium and a transmission medium.

Although this disclosure includes detailed descriptions of various detailed implementation examples, it should be understood that the details describe features of specific exemplary embodiments, and are not intended to limit the scope of the invention or claims proposed in this disclosure.

Features individually described in exemplary embodiments in this disclosure may be implemented by a single exemplary embodiment. Conversely, various features that are described for a single exemplary embodiment in this disclosure may also be implemented by a combination or appropriate sub-combination of multiple exemplary embodiments. Further, in this disclosure, the features may operate in particular combinations, and may be described as if initially the combination were claimed. In some cases, one or more features may be excluded from a claimed combination, or a claimed combination may be modified in a sub-combination or modification of a sub-combination.

Similarly, although operations are described in a particular order in a drawing, it should not be understood that it is necessary to perform the operations in a particular order or order, or that all operations are required to be performed in order to obtain a desired result. Multitasking and parallel processing can be useful in certain cases. In addition, it should not be understood that various device components must be separated in all exemplary embodiments of the embodiments, and the above-described program components and devices may be packaged into a single software product or multiple software products.

Exemplary embodiments disclosed herein are illustrative only and are not intended to limit the scope of the disclosure. Those skilled in the art will recognize that various modifications may be made to the exemplary embodiments without departing from the spirit and scope of the claims and their equivalents.

Accordingly, it is intended that this disclosure include all other substitutions, modifications and variations falling within the scope of the following claims.

What is claimed is:

1. A radio frequency (RF) single pole double throw (SPDT) switch device for differential signal conversion, the RF SPDT switch device comprising:
a central metal line;
a first metal line and a second metal line connected to a first direction side of the central metal line; and
a third metal line and a fourth metal line connected to a second direction side of the central metal line,
wherein an antenna port is connected to one end of the central metal line and the other end is open,
wherein a first differential port is connected to one end in a direction in which the first metal line and the second metal line face each other, and
wherein a second differential port is connected to one end in a direction in which the third metal line and the fourth metal line face each other.

2. The RF SPDT switch device of claim 1, wherein:
a length of the central metal line is half of a wavelength (Δ) of a signal input as the antenna signal, and
a length of each of the first metal line, the second metal line, the third metal line, and the fourth metal line is Δ/4.

3. The RF SPDT switch device of claim 1, wherein:
the first differential port is one of a transmission (Tx) port or a reception (Rx) port, and
the second differential port is the other of the transmission port or the reception port.

4. The RF SPDT switch device of claim 3, wherein:
a first transistor is connected to one end of the first metal line and the second metal line facing each other, and
a second transistor connected to ground (GND) is connected to the other end of each of the first metal line and the second metal line.

5. The RF SPDT switch device of claim 4, wherein:
a third transistor is connected to one end of the third metal line and the fourth metal line facing each other, and
a fourth transistor connected to GND is connected to the other end of each of the third metal line and the fourth metal line.

6. The RF SPDT switch device of claim 5, wherein:
based on a high signal being input to a gate of each of the second transistor or the fourth transistor, each of the second transistor or the fourth transistor is controlled to be connected to the GND, and
based on a low signal being input to the gate of each of the second transistor or the fourth transistor, each of the second transistor or the fourth transistor is controlled to be opened.

7. The RF SPDT switch device of claim 5, wherein:
based on a high signal being input to a gate of each of the first transistor or the third transistor, a plurality of metal lines connected to each of the first transistor or the third transistor are controlled to be connected, and
based on a low signal being input to the gate of each of the first transistor and the third transistor, the first transistor and the third transistor are controlled to be opened.

8. The RF SPDT switch device of claim 5, wherein:
based on the first differential port being a transmitting port, the second differential port being a receiving port, and a single-ended reception signal being input from the antenna port:
the first transistor is closed,
the second transistor is opened,
the third transistor is opened, and
the fourth transistor is short-circuited.

9. The RF SPDT switch device of claim 8, wherein:
the single-ended reception signal is converted into a differential signal and received at the reception port.

10. The RF SPDT switch device of claim 5, wherein:
based on the first differential port being a transmitting port, the second differential port being a receiving port, and a single-ended transmission signal being input from the antenna port:
the first transistor is opened,
the second transistor is short-circuited,
the third transistor is short-circuited, and
the fourth transistor is opened.

11. The RF SPDT switch device of claim 10, wherein:
the single-ended reception signal is converted into a differential signal and transmitted at the transmission port.

12. A Multi-channel chip comprising:
a transmission circuit;
a reception circuit; and
a radio frequency (RF) single pole double throw (SPDT) switch device for differential signal conversion arranged between the transmission circuit and the reception circuit,
wherein the RF SPDT switch device connected to the transmission circuit and the reception circuit includes:
a central metal line;
a first metal line and a second metal line connected to a first direction side of the central metal line; and
a third metal line and a fourth metal line connected to a second direction side of the central metal line,
wherein an antenna port is connected to one end of the central metal line and the other end is open,
wherein a first differential port is connected to one end in a direction in which the first metal line and the second metal line face each other, and
wherein a second differential port is connected to one end in a direction in which the third metal line and the fourth metal line face each other.

13. The Multi-channel chip of claim 12, wherein:
a length of the central metal line is half of a wavelength (Δ) of a signal input as the antenna signal, and
a length of each of the first metal line, the second metal line, the third metal line, and the fourth metal line is Δ/4.

14. The Multi-channel chip of claim 12, wherein:
the first differential port is one of a transmission (Tx) port or a reception (Rx) port, and
the second differential port is the other of the transmission port or the reception port.

15. The Multi-channel chip of claim 14, wherein:
a first transistor is connected to one end of the first metal line and the second metal line facing each other, and
a second transistor connected to ground (GND) is connected to the other end of each of the first metal line and the second metal line.

16. The Multi-channel chip of claim 15, wherein:
a third transistor is connected to one end of the third metal line and the fourth metal line facing each other, and
a fourth transistor connected to GND is connected to the other end of each of the third metal line and the fourth metal line.

17. The Multi-channel chip of claim 16, wherein:
based on a high signal being input to a gate of each of the second transistor or the fourth transistor, each of the second transistor or the fourth transistor is controlled to be connected to the GND, and
based on a low signal being input to the gate of each of the second transistor or the fourth transistor, each of the second transistor or the fourth transistor is controlled to be opened.

18. The Multi-channel chip of claim 17, wherein:
based on a high signal being input to a gate of each of the first transistor or the third transistor, a plurality of metal lines connected to each of the first transistor or the third transistor are controlled to be connected, and
based on a low signal being input to the gate of each of the first transistor and the third transistor, the first transistor and the third transistor are controlled to be opened.

19. A device including a multi-channel chip, the device comprises:
at least one processor; and
at least one transceiver,
wherein the at least one processor is configured to:
receive a single-ended signal from an external device through the at least one transceiver; and
convert the single-ended signal into a differential-ended signal,
wherein the multi-channel chip includes:
a transmission circuit;
a reception circuit; and
a radio frequency (RF) single pole double throw (SPDT) switch device for differential signal conversion arranged between the transmission circuit and the reception circuit,
wherein the RF SPDT switch device connected to the transmission circuit and the reception circuit includes:
a central metal line;
a first metal line and a second metal line connected to a first direction side of the central metal line; and
a third metal line and a fourth metal line connected to a second direction side of the central metal line,
wherein an antenna port is connected to one end of the central metal line and the other end is open,
wherein a first differential port is connected to one end in a direction in which the first metal line and the second metal line face each other, and
wherein a second differential port is connected to one end in a direction in which the third metal line and the fourth metal line face each other.
